(19) United States
(12) Patent Application Publication
(10) Pub. No.: US 2020/0305238 A1
(43) Pub. Date: Sep. 24, 2020

(54) STRUCTURE

(71) Applicant: KYOCERA Corporation, Kyoto-shi, Kyoto (JP)

(72) Inventors: Yasunori KAWANABE, Kirishima-shi, Kagoshima (JP); Daiki WATANABE, Kirishima-shi, Kagoshima (JP); Yoshihiro OKAWA, Kirishima-shi, Kagoshima (JP)

(21) Appl. No.: 16/649,379

(22) PCT Filed: Sep. 20, 2018
(86) PCT No.: PCT/JP2018/034879

§ 371 Date: Mar. 20, 2020

(30) Foreign Application Priority Data
Sep. 28, 2017 (JP) 2017-188492

(51) Int. Cl. H05B 3/14; H05B 3/00; H05B 3/06; H05B 3/10; H05B 3/74

(52) U.S. Cl. CPC H05B 3/141; H05B 3/0004; H05B 3/74; H05B 3/10; H05B 3/06

(57) ABSTRACT

A structure of the present disclosure includes a substrate made of an aluminum nitride-based ceramic, a power supply terminal made of tungsten or molybdenum, a bonding layer located between the substrate and the power supply terminal to be in contact with each thereof, and an internal electrode electrically connected to the power supply terminal. Then, in the bonding layer, a total of components constituting the power supply terminal and aluminum nitride is 90 vol % or more in a total volume of 100 vol % constituting the bonding layer.

### FIELD

The present invention relates to a structure.

### BACKGROUND

Ceramics are more excellent in heat resistance than metals and resins. In particular, an aluminum nitride-based ceramic has a high thermal conductivity among ceramics, and hence, is used as the structure for mounting or holding an object to be treated when heat-treating the object to be treated such as various elements and components.

When the structure is used as a heater for heat-treating the object to be treated, an internal electrode that is located inside the structure and generates heat by passing current therethrough, and a power supply terminal that connects the internal electrode to an external power source are needed.

For example, Patent Literature 1 discloses an AlN heater including an AlN sintered body base material, a resistance heating element provided on one surface side of the AlN sintered body base material, a terminal insertion hole that is provided in the AlN sintered body base material and is communicated from the other surface side to the one surface side, a metal terminal fitted into the terminal insertion hole and bonded to the resistance heating element, and an AlN sintered body lid attached to the AlN sintered body base material so as to cover the resistance heating element. The terminal has a substantially columnar shape, and a bonding surface with the resistance heating element is reduced in diameter.

### CITATION LIST

### Patent Literature

Patent Literature 1: Japanese Patent Application Publication No. 2004-087392

### SUMMARY

A structure of the present disclosure includes a substrate made of an aluminum nitride-based ceramic, a power supply terminal made of tungsten or molybdenum, a bonding layer located between the substrate and the power supply terminal to be in contact with each thereof, and an internal electrode electrically connected to the power supply terminal. Then, in the bonding layer, a total of components constituting the power supply terminal and aluminum nitride is 90 vol % or more in a total volume of 100 vol % constituting the bonding layer.

### BRIEF DESCRIPTION OF DRAWINGS

FIG. 1 is a plan view schematically illustrating an example of a structure of the present disclosure.

FIG. 2 is an enlarged view near a power supply terminal in a cross-sectional view taken along line II-II in FIG. 1.

### DESCRIPTION OF EMBODIMENTS

In recent years, when heating an object to be treated to a high temperature (hereinafter, referred to as high-temperature heating), a structure may be heated to a temperature exceeding about 600° C. In such a case, when the structure and a power supply terminal are in direct contact with each other as in the ALN heater described in Patent Literature 1 and high-temperature heating and cooling are repeated, since a stress caused by a difference in a thermal expansion coefficient between the structure made of an aluminum nitride-based ceramic and the power supply terminal made of metal is repeatedly applied, a crack may be generated in the structure. The structure means, for example, a heater on which a wafer is placed.

The structure of the present disclosure is less likely to crack and can be used for a long period of time. Hereinafter, the structure of the present disclosure will be described in detail with reference to the drawings.

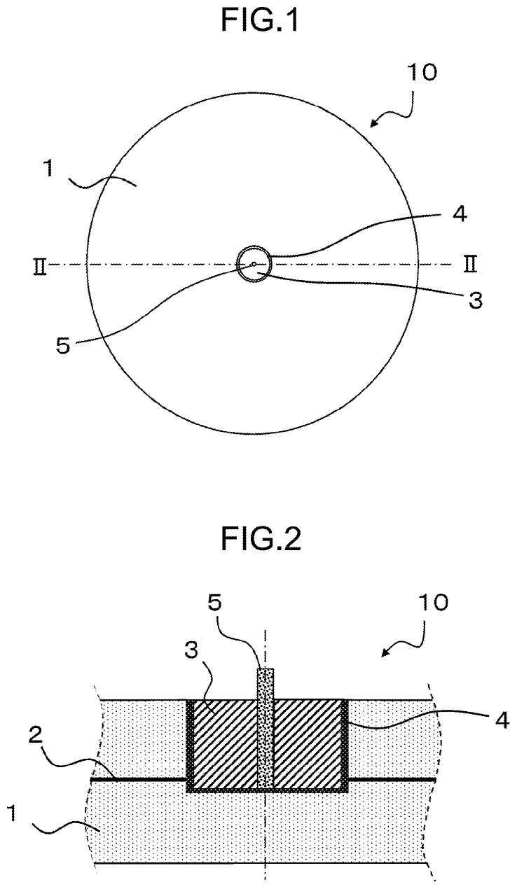

As illustrated in FIGS. 1 and 2, a structure 10 of the present disclosure includes a substrate 1, a power supply terminal 3, a bonding layer 4 located between the substrate 1 and the power supply terminal 3 to be in contact with each thereof, and an internal electrode 2 electrically connected to the power supply terminal 3. As illustrated in FIG. 2, the internal electrode 2 is an electrode located inside the substrate 1. The power supply terminal 3 and the internal electrode 2 may be directly connected to each other, or the power supply terminal 3 and the internal electrode 2 may be connected through the bonding layer 4.

Although FIGS. 1 and 2 illustrate an example in which the substrate 1 has a disk shape and the power supply terminal 3 has a columnar shape, the present invention is not limited thereto, and the substrate 1 and the power supply terminal 3 may have any shape.

The power supply terminal 3 may be located at any position as long as it is in contact with the bonding layer 4 and is connected to the internal electrode 2. For example, as illustrated in FIG. 2, the power supply terminal 3 may be located inside the substrate 1.

The substrate 1 in the structure 10 of the present disclosure is made of an aluminum nitride-based ceramic. In the aluminum nitride-based ceramic, aluminum nitride accounts for 70 mass % or more in 100 mass % of all components constituting the aluminum nitride-based ceramic.

Then, a material of the substrate 1 can be checked by the following method. First of all, a constituent component of the substrate 1 is identified by measurement using an X-ray diffractometer (XRD) and identifying an obtained value of 2θ (where 2θ is a diffraction angle) with a JCPDS card. Subsequently, quantitative analysis of the substrate 1 is performed using an ICP (Inductively Coupled Plasma) emission spectrometer (ICP). At this time, if the constituent component identified by XRD is aluminum nitride, and the value converted from the content of aluminum (Al) measured by ICP to aluminum nitride (AlN) is 70 mass % or greater, the material is an aluminum nitride-based ceramic.

The power supply terminal 3 in the structure 10 of the present disclosure is made of tungsten or molybdenum. The thermal expansion coefficients of tungsten and molybdenum among metals are close to that of an aluminum nitride-based ceramic, and tungsten and molybdenum can maintain strength even at a temperature exceeding about 600° C. It should be noted that the fact that the power supply terminal 3 is made of tungsten or molybdenum means that tungsten or molybdenum accounts for 99.5 mass % or more in 100 mass % of all components constituting the power supply terminal 3.

In the bonding layer 4 in the structure 10 of the present disclosure, a total of components constituting the power supply terminal 3 and aluminum nitride is 90 vol % or more in a total volume of 100 vol % constituting the bonding layer 4. The components constituting the power supply terminal 3 are tungsten or molybdenum.

As described above, since the bonding layer 4 has a total of 90 vol % or more of the components constituting the power supply terminal 3 and aluminum nitride, the power supply terminal 3 and the substrate 1 are chemically bonded firmly through the bonding layer 4. Since the thermal expansion coefficient of the bonding layer 4 is a value between those of the power supply terminal 3 and the substrate 1, when high-temperature heating and cooling are repeated, the stress generated due to a difference in a thermal expansion coefficient between the power supply terminal 3 and the substrate 1 can be alleviated by the bonding layer 4, and the substrate 1 is less likely to crack. Therefore, by satisfying the above configuration, the structure 10 of the present disclosure is less likely to crack even when high-temperature heating and cooling are repeated, and can be used for a long period of time.

If in the bonding layer 4, a total of the components constituting the power supply terminal 3 and aluminum nitride is 95 vol % or more in the total volume of 100 vol % constituting the bonding layer 4, the power supply terminal 3 and the substrate 1 are chemically bonded more firmly through the bonding layer 4.

The content of components constituting the bonding layer 4 can be measured as follows. First of all, the substrate 1 is cut to have a cross-sectional shape as illustrated in FIG. 2 and polished using a cross-section polisher (CP) to obtain a polished surface. Subsequently, the polished surface is irradiated with an electron beam using a wavelength-dispersive X-ray spectrometer (WDS) attached to a scanning electron microscope (SEM), to take black-and-white photographs respectively mapping tungsten, molybdenum, aluminum and nitrogen. Here, a portion where aluminum and nitrogen are simultaneously present is regarded as aluminum nitride. Then, locations where the components (tungsten, molybdenum and aluminum nitride) are present are respectively traced and painted black, and image analysis is performed using a method of particle analysis of image analysis software “A-zo kun” (registered trademark, produced by Asahi Kasei Engineering Corporation, and hereinafter when the image analysis software “A-zo kun” is described, it means the image analysis software produced by Asahi Kasei Engineering Corporation). Then, values of area ratios (area %) of tungsten, molybdenum and aluminum nitride calculated by the image analysis can be directly regarded as values of volume ratios (vol %). As analysis conditions of “A-zo kun”, brightness of particles can be “dark”, binarization method can be “automatic”, and shading can be “present”.

In the bonding layer 4 in the structure 10 of the present disclosure, the content of the components constituting the power supply terminal 3 may be 20 vol % or greater and 80 vol % or less in the total volume of 100 vol % constituting the bonding layer 4. When such a configuration is satisfied, the power supply terminal 3 and the substrate 1 can be more firmly bonded through the bonding layer 4, and conductivity of the bonding layer 4 can be increased.

In particular, from the viewpoint of bonding strength and conductivity, the content of the components constituting the power supply terminal 3 in the bonding layer 4 may be, for example, 45 vol % or greater and 70 vol % or less. On the other hand, the content of aluminum nitride in the bonding layer 4 may be, for example, 30 vol % or greater and 55 vol % or less.

The bonding layer 4 in the structure 10 of the present disclosure may include an aluminum nitride lump with an aspect ratio that is 5 or greater. The aspect ratio is a value obtained by dividing a major axis of the aluminum nitride lump observed in a cross-section illustrated in FIG. 2 by a minor axis. The major axis refers to a length of a line segment at which the length is the maximum when drawing a straight line through the aluminum nitride lump, and measuring the length of the line segment between two points where the straight line and an outer edge of the aluminum nitride lump intersect. When a straight line is drawn at a center of a major axis line segment so as to be orthogonal to the major axis line segment, the minor axis is a length of a line segment between two points where the straight line and the outer edge of the aluminum nitride lump intersect.

When such a configuration is satisfied, even if the crack is generated in the bonding layer 4 when high-temperature heating and cooling are repeated, growth of the crack can be suppressed by the aluminum nitride lump with an aspect ratio that is 5 or greater, and thus the structure 10 of the present disclosure can be used for a longer period of time.

The major axis of the aluminum nitride lump may be 50 μm or greater and 400 μm or less, and the minor axis of the aluminum nitride lump may be 10 μm or greater to 40 μm or less.

The present or absence of the aluminum nitride lump with an aspect ratio that is 5 or greater in the bonding layer 4 can be confirmed by the following method. First of all, the substrate 1 is cut to have a cross-sectional shape as illustrated in FIG. 2 and polished using the CP to obtain the polished surface. Subsequently, the polished surface is irradiated with the electron beam using the WDS attached to the SEM, to take the black-and-white photographs respectively mapping aluminum and nitrogen. Here, the lump in which aluminum and nitrogen are simultaneously present is regarded as the aluminum nitride lump. Then, the aluminum nitride lump is traced and painted black, and the image analysis is performed using the method of particle analysis of the image analysis software “A-zo kun”. Since the major axis and the minor axis of the aluminum nitride lump are calculated by the image analysis, the aspect ratio is calculated by dividing the major axis by the minor axis, and the presence of the aluminum nitride lump with an aspect ratio that is 5 or greater can be confirmed. As the analysis conditions of “A-zo kun”, the brightness of the particles can be “dark”, the binarization method can be “automatic”, and the shading can be “present”.

The internal electrode 2 in the structure 10 of the present disclosure may be made of any material as long as it is conductive, however, like the bonding layer 4, the total of the components constituting the power supply terminal 3 and aluminum nitride may be 90 vol % or more in the total volume of 100 vol % constituting the internal electrode 2. When such a configuration is satisfied, the internal electrode 2 has conductivity and has a small difference in thermal expansion coefficient from the substrate 1.

From the viewpoint of further reducing the difference in thermal expansion coefficient from the substrate 1, in the internal electrode 2, the total of the components constituting the power supply terminal 3 and aluminum nitride may be 95 vol % or more in the total volume of 100 vol % constituting the internal electrode 2.

In the structure 10 of the present disclosure, the content of the components constituting the power supply terminal 3 in the internal electrode 2 may be greater than the content of the components constituting the power supply terminal 3 in the bonding layer 4. When such a configuration is satisfied, current can readily flow from the bonding layer 4 to the internal electrode 2, and heat generation in the bonding layer 4 can be reduced.

In particular, in the structure 10 of the present disclosure, if the content of the components constituting the power supply terminal 3 in the internal electrode 2 is greater than the content of the components constituting the power supply terminal 3 in the bonding layer 4 by 10 vol % or greater, the heat generation in the bonding layer 4 can be further reduced.

The content of the components constituting the power supply terminal 3 in the internal electrode 2 may be, for example, 65 vol % or greater and 90 vol % or less. On the other hand, the content of aluminum nitride in the bonding layer 4 may be, for example, 10 vol % or greater and 35 vol % or less.

The content of components constituting the internal electrode 2 can be calculated by the same method as the method for measuring the content of the components constituting the bonding layer 4 described above.

The bonding layer 4 in the structure 10 of the present disclosure includes particles of the components constituting the power supply terminal 3 (hereinafter, also simply referred to as the particles), and an average value of equivalent circle diameters of the particles may be 3 μm or greater and 12 μm or less. When such a configuration is satisfied, the power supply terminal 3 and the substrate 1 can be more firmly bonded through the particles, and the conductivity of the bonding layer 4 can be further increased by the presence of the particles.

In the bonding layer 4, the presence or absence of the particles and the average value of the equivalent circle diameters of the particles can be measured as follows. First of all, the substrate 1 is cut to have a cross-sectional shape as illustrated in FIG. 2 and polished using the CP to obtain the polished surface. Subsequently, the bonding layer 4 of the polished surface is irradiated with the electron beam using the WDS attached to the SEM, to take the black-and-white photograph mapping the component (tungsten or molybdenum) constituting the power supply terminal 3. If there are the particles containing tungsten or molybdenum, they are the particles of the component constituting the power supply terminal 3. Then, the particles are traced and painted black, and the image analysis is performed using the method of particle analysis of the image analysis software “A-zo kun”, so that the average value of the equivalent circle diameters of the particles can be calculated. As the analysis conditions of “A-zo kun”, the brightness of the particles can be “dark”, the binarization method can be “automatic”, and the shading can be “present”.

The power supply terminal 3 in the structure 10 of the present disclosure may include a metal rod 5 connected to the power supply terminal 3 as illustrated in FIGS. 1 and 2. The metal rod 5 is for connecting an external power supply and the power supply terminal 3. The metal rod 5 may be made of any material as long as it is conductive, and is made of, for example, nickel.

Then, an example of a method for manufacturing the structure 10 of the present disclosure will be described. Here, a case where the power supply terminal 3 is made of tungsten will be described.

First of all, a green sheet of aluminum nitride is prepared by a known method. Subsequently, tungsten powder and aluminum nitride powder are prepared as solid powders, and a first paste containing the solid powders and serving as the internal electrode 2 is prepared. Subsequently, after printing the first paste at an arbitrary position on the green sheet, a plurality of green sheets are laminated by a lamination method to produce a molded body. Subsequently, the molded body is fired in a nitrogen gas to obtain the substrate 1 having the internal electrode 2 therein.

Subsequently, a metal solid made of tungsten is prepared as the power supply terminal 3. The tungsten powder and the aluminum nitride powder are prepared as the solid powders, and a second paste containing the solid powders and serving as the bonding layer 4 is prepared.

Subsequently, a hole for inserting the power supply terminal 3 therein is made in the substrate 1, and the hole is made so that the internal electrode 2 is exposed to an inner wall of the hole. Then, the second paste is applied to the inner wall of the hole.

Subsequently, the power supply terminal 3 is inserted into the hole, so as to be heat-treated. A heat treatment temperature at this time is lower than or equal to a firing temperature of the substrate 1. Thus, the structure 10 of the present disclosure is obtained.

In order to set the content of tungsten in the bonding layer 4 at 20 vol % or greater and 80 vol % or less, a proportion of the tungsten powder in the second paste can be adjusted.

In order to make the content of tungsten in the internal electrode 2 greater than the content of tungsten in the bonding layer 4, the proportion of the tungsten powder in the first paste can be made greater than that in the second paste. In this case, the content of tungsten in the internal electrode 2 may be adjusted to be greater than the content of tungsten in the bonding layer 4 by 10 vol % or greater.

In order for the bonding layer 4 to contain the aluminum nitride lump with an aspect ratio that is 5 or greater, a part of the aluminum nitride powders contained in the second paste can be replaced with the aluminum nitride lump with an aspect ratio that is 5 or greater.

In order for the bonding layer 4 to contain the tungsten particles with an average value of the equivalent circle diameter that is 3 μm or greater and 12 μm or less, the tungsten powders with an average particle diameter that is 0.3 μm or greater and 1.2 μm or less can be used for the second paste, and the heat treatment temperature after inserting the power supply terminal 3 into the hole can be set at 1500° C. or higher and 1800° C. or lower. By performing the heat treatment at such a heat treatment temperature, the tungsten powder is agglomerated and grown, and the tungsten particles with an average value of the equivalent circle diameter that is 3 μm or greater and 12 μm or less can be obtained.

### REFERENCE SIGNS LIST

1 substrate
2 internal electrode
3 power supply terminal
4 bonding layer
5 metal rod
10 structure

1. A structure comprising:
a substrate made of an aluminum nitride-based ceramic;
a power supply terminal made of tungsten or molybdenum;
a bonding layer located between the substrate and the power supply terminal to be in contact with each thereof; and
an internal electrode electrically connected to the power supply terminal, wherein
a total of components constituting the power supply terminal and aluminum nitride in the bonding layer is 90 vol % or more in a total volume of 100 vol % constituting the bonding layer.

2. The structure according to claim 1, wherein a content of the components constituting the power supply terminal in the bonding layer is 20 vol % or greater and 80 vol % or less in the total volume of 100 vol % constituting the bonding layer.

3. The structure according to claim 1, wherein the bonding layer contains an aluminum nitride lump with an aspect ratio that is 5 or greater.

4. The structure according to claim 1, wherein a content of the components constituting the power supply terminal in the internal electrode is greater than the content of the components constituting the power supply terminal in the bonding layer.

5. The structure according to claim 4, wherein the content of the components constituting the power supply terminal in the internal electrode is greater than the content of the components constituting the power supply terminal in the bonding layer by 10 vol % or greater.

6. The structure according to claim 1, wherein
the bonding layer contains particles of the components constituting the power supply terminal, and
an average value of equivalent circle diameters of the particles is 3 μm or greater and 12 μm or less.
